(19) United States
(12) Patent Application Publication
(10) Pub. No.: US 2020/0086758 A1
(43) Pub. Date: Mar. 19, 2020

(54) Method for Measuring Capacity of Energy Storage Devices in Hybrid Bus

(71) Applicant: Jiangnan University, Wuxi (CN)

(72) Inventors: Wenzhou LU, Wuxi (CN); Haiying CHEN, Wuxi (CN); Yanwei LIU, Wuxi (CN); Jiqiang XU, Wuxi (CN)

(21) Appl. No.: 16/684,714

(22) Filed: Nov. 15, 2019

Related U.S. Application Data
(63) Continuation of application No. PCT/CN2017/115624, filed on Dec. 12, 2017.

(30) Foreign Application Priority Data
Oct. 10, 2017 (CN) 201710940576.X

(51) Int. Cl. B60L 58/10; G01R 31/382; G01R 31/367; B60L 50/60; B60K 15/03; B60K 6/28; B60L 50/40; H01M 10/48

(52) U.S. Cl. CPC B60L 58/10; H01M 2220/20; G01R 31/367; B60L 50/66; B60K 15/03; B60K 6/28; B60L 50/40; H01M 10/48; B60L 2200/18; B60Y 2200/92; B60Y 2200/143; B60K 2015/03217; B60Y 2400/112; B60Y 2400/114; G01R 31/382

(57) ABSTRACT

The present disclosure discloses a method for measuring capacity of energy storage devices in a hybrid bus, and belongs to the technical field of energy management and control of hybrid buses. The method comprises the steps of obtaining required power P_{usage} of the hybrid bus for round trips on a selected bus line for for one or more times and then obtaining average required power P_{usage avg}; determining energy storage capacity of a short-term energy storage device of the hybrid bus, specifically including the step that Fourier transformation is carried out on the required power P_{usage} to obtain a relation model between the required power P_{usage} and time periods; and determining energy storage capacity of a long-term energy storage device of the hybrid bus, specifically including the steps that n supply and demand mismatch power P_{Δi} are calculated, wherein P_{Δi}=P_{usage avg}−P_{usage}, that the obtained n P_{Δi} are connected end to end, and that then a maximum value of the sum of any q connected data is calculated, wherein the obtained maximum value is the energy storage capacity of the long-term energy storage device.

### TECHNICAL FIELD

The present disclosure relates to a method for measuring capacity of energy storage devices in a hybrid bus, and belongs to the technical field of energy management and control of hybrid buses.

### BACKGROUND

Automobile vehicles purely adopting fossil fuel cause great environmental pollution. For example, fossil-fueled vehicles are one of the sources generating PM2.5, which has attracted extensive attention currently. So, all countries in the world are actively developing and popularizing the related technologies of pure electric vehicles. However, pure electric vehicles have been stuck by the problems of low battery energy density, inconvenient charging facilities and the like. Moreover, the technical problems and popularization difficulty are great.

Therefore, currently, a good method for compromise is to use hybrid vehicles as a transition means to electric vehicles. In addition, through the pilot of various hybrid buses, the government expects to arouse people's attention through demonstration and promotes the application of related technologies. However, there is no rapid and accurate measurement method at present about how to determine the capacity of two kinds of power sources in a hybrid bus (considering power sources as energy storage devices, i.e., determining the capacity of the energy storage devices).

If capacity of selected batteries for an ordinary oil-electricity hybrid bus is too large, unnecessary cost, weight, and power consumption will be increased; however, when capacity of batteries is too small, the bus will burn too much fossil fuel and pollute the air. Therefore, it is of great significance to find a calculation method for determining the capacity of the energy storage devices of the hybrid bus.

### SUMMARY

The present disclosure mainly aims to provide a method for measuring capacity of energy storage devices in a hybrid bus so as to overcome the defects in the prior art.

In order to achieve the abovementioned purposes of the present disclosure, the technical scheme adopted by the present disclosure includes the following content.

The method for measuring the capacity of the energy storage devices in the hybrid bus according to the example of the present disclosure includes the following steps:

obtaining an actual load energy demand value of the hybrid bus for round trips on a selected bus line for one or more times per unit time, namely, required power P_{usage}, and then adding up and averaging the corresponding required power within the needed time range of the hybrid bus for round trips on the selected bus line for one or more times so as to obtain average required power P_{usage avg};

determining energy storage capacity of a short-term energy storage device of the hybrid bus, specifically including the steps of

carrying out Fourier transformation on the required power P_{usage} to obtain a relation model between the required power P_{usage} and time periods, wherein a vertical axis is required power data P_{usage}, an abscissa axis is time period values T=1/f, and f is frequency,

carrying out per-unit value normalization on the required power corresponding to each time period within not more than half of the time in the time range required by the hybrid bus for round trips on the selected bus line for one or more times, so as to obtain a specific value Pᵢ after per-unit value normalization, and accumulating the required power obtained after per-unit value normalization period by period to obtain an accumulated value ΣPᵢ of a series of required power values after per-unit value normalization, wherein 0<Pᵢ<1, and

establishing a relation curve of the accumulated value and the time periods, selecting one short and long term critical percentage k from the relation curve, determining the period Tₖ corresponding to k and judging that the period duration smaller than Tₖ needs to be buffered by the short-term energy storage device, so as to determine the energy storage capacity of the short-term energy storage device as P_{usage avg}*Tₖ, wherein ΣPᵢ corresponds to the percentage of the required power accumulated value with the period greater than or equal to the corresponding time period Tᵢ of the abscissa axis to the whole required power total quantity, and 0.2<k<0.4; and

determining the energy storage capacity of a long-term energy storage device of the hybrid bus, specifically including the steps of calculating n supply and demand mismatch power P_{Δi}, wherein P_{Δi}=P_{usage avg}−P_{usage}, connecting the obtained n P_{Δi} end to end, and then calculating a maximum value of the sum of any q connected data, wherein the obtained maximum value is the energy storage capacity of the long-term energy storage device, n is a positive integer, and q is a natural number which is greater than or equal to 1 but smaller than or equal to n.

Optionally, in the process of determining the energy storage capacity of the short-term energy storage device, per-unit value normalization is carried out on the required power corresponding to each time period within half of the time required by the hybrid bus for round trips on the selected bus line for one or more times.

Optionally, in the process of determining the energy storage capacity of the short-term energy storage device, the required power corresponding to each time period within half of the time required by the hybrid bus for round trips on the selected bus line for one or more times is added up to obtain the required power total quantity, and then the required power of each period is divided by the required power total quantity, so that a series of decimals Pᵢ are obtained, and per-unit value normalization is achieved.

Optionally, in the process of determining the energy storage capacity of the short-term energy storage device, the required power values after per-unit value normalization are accumulated period by period from a value with a large period, and the accumulated value ΣPᵢ of a series of required power values after per-unit value normalization is obtained, wherein the value with the large period is the value with low frequency and small fluctuation.

Optionally, the method further includes the steps of calculating a volume of liquefied fuel needing storing in the long-term energy storage device according to the energy storage capacity of the long-term energy storage device, wherein the volume of the liquefied fuel is obtained by dividing the energy storage capacity of the long-term energy storage device by energy density of the liquefied fuel per unit volume and then dividing the result by efficiency for burning the liquefied fuel.

Optionally, the method further includes the steps of multiplying the energy storage capacity of the long-term energy storage device and the energy storage capacity of the short-term energy storage device by a margin coefficient C₁ of the capacity of the long-term energy storage device and a margin coefficient C₂ of the capacity of the short-term energy storage device, wherein 1≤C1≤2, and 1≤C2≤2.

Optionally, the values of C₁ and C₂ are related to extra influence factors, and the extra influence factors include at least one from efficiency of an electric power conversion device, safety margins and safety limits of the energy storage devices, load increase of an air conditioner in winter and summer and drive power demand increase at rush hours.

Optionally, load energy demands of the hybrid bus include a drive force energy demand needed for vehicle advancing and an energy demand needed for normal safe operation of vehicle-mounted equipment.

Optionally, the long-term energy storage device is a fuel energy storage device.

Optionally, the short-term energy storage device is a battery or a capacitive energy storage device.

Optionally, a long and short term critical percentage k=0.3 is selected.

The present disclosure has the beneficial effects:

compared with the prior art, the present disclosure has the advantages that the method for measuring the capacity of the energy storage devices in the hybrid bus provided by the present disclosure can rapidly and accurately determine the capacity of the short-term energy storage device and the long-term energy storage device in the hybrid bus by recording or obtaining historical required power data of the hybrid bus, so as to greatly reduce the cost of the energy storage devices and the whole bus on the premise of ensuring continuous and reliable running of the hybrid bus.

### BRIEF DESCRIPTION OF FIGURES

FIG. 1 is a structural schematic diagram of a hybrid bus system;

FIG. 2 is historical data of required power of a hybrid bus on a selected bus line in example 1 of the present disclosure;

FIG. 3 is a corresponding diagram of a required power-period relationship obtained after Fourier transformation is performed on historical data of the required power in example 1 of the present disclosure; and

FIG. 4 is a curve diagram of a relationship between accumulated values and periods of the required power values after per-unit value normalization in example 1 of the present disclosure.

### DETAILED DESCRIPTION

In order to make objects, technical schemes and advantages of the present disclosure more clear, detailed description will be further made to implementation modes of the present disclosure in conjunction with drawings.

### Example 1

The example of the present disclosure provides a method for measuring capacity of energy storage devices in a hybrid bus, including the following steps:

Step 1: obtaining an actual load energy demand value of the hybrid bus for round trips on a selected bus line for one or more times per unit time, namely, required power P_{usage}, and then adding up and then averaging the corresponding required power within the needed time range of the hybrid bus for round trips on the selected bus line for one or more times so as to obtain average required power P_{usage avg};

Step 2: determining energy storage capacity of a short-term energy storage device of the hybrid bus, specifically including the step of

carrying out Fourier transformation on the required power P_{usage} to obtain a relation model between the required power P_{usage} and time periods, wherein a vertical axis is required power data P_{usage}, an abscissa axis is time period values T=1/f, and f is frequency;

Step 3: carrying out per-unit value normalization on the required power corresponding to each time period within not more than half of the time in the time range required by the hybrid bus for round trips on the selected bus line for one or more times, so as to obtain a specific value Pᵢ after per-unit value normalization, and accumulating the required power values obtained after per-unit value normalization period by period to obtain an accumulated value ΣPᵢ of a series of required power values after per-unit value normalization, wherein 0<Pᵢ<1;

Step 4: establishing a relation curve of the accumulated value and the time periods, selecting one short and long term critical percentage k from the relation curve, determining the period Tₖ corresponding to k and judging that the period duration smaller than Tₖ needs to be buffered by the short-term energy storage device, so as to determine the energy storage capacity of the short-term energy storage device as P_{usage avg}*Tₖ, wherein ΣPᵢ corresponds to the percentage of the required power accumulated value with the period greater than or equal to the corresponding time period Tᵢ of the abscissa axis to the whole required power total quantity, and 0.2<k<0.4; and

Step 5: determining energy storage capacity of a long-term energy storage device of the hybrid bus, specifically including the steps of calculating n supply and demand mismatch power P_{Δi} wherein P_{Δi}=P_{usage avg}−P_{usage}, connecting the obtained n P_{Δi} end to end, and then calculating a maximum value of the sum of any q connected data, wherein the obtained maximum value is the energy storage capacity of the long-term energy storage device, n is a positive integer, and q is a natural number which is greater than or equal to 1 but smaller than or equal to n.

### Example 2

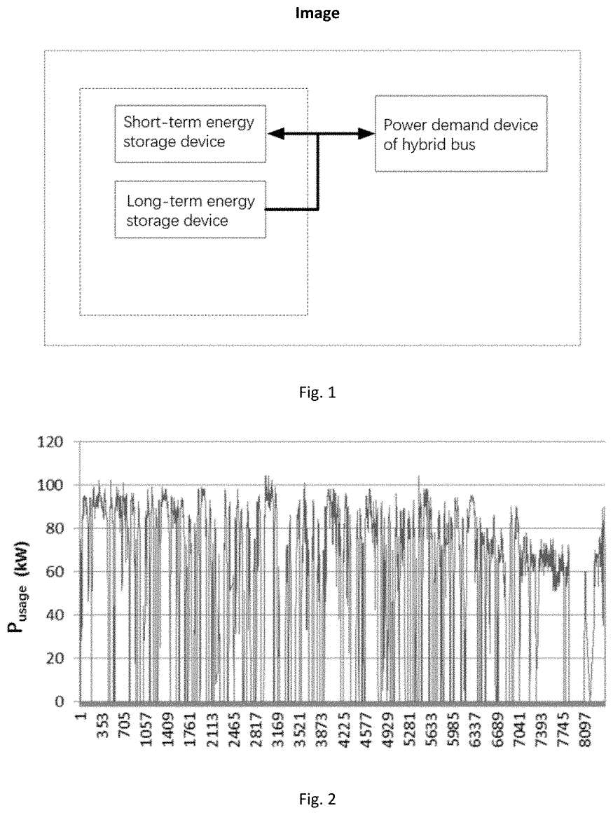

The present example provides a typical implementation case, a considered application object is a hybrid bus, and the systematical structural diagram of the hybrid bus is shown as FIG. 1.

The hybrid bus generally has two kinds of power or energy sources, which can be regarded as energy storage devices of the hybrid bus. The energy storage devices are in an ordinary oil-electricity hybrid type, oil generally is gasoline and can also be other fuel as a replacement of gasoline. For example, compressed natural gas, propane, hydrogen, ethyl alcohol and other fuel are used for replacement, and the oil-electricity hybrid type energy storage devices are named as fuel-electricity hybrid type energy storage devices.

A fuel energy storage device in the energy storage devices serves as a long-term energy source for meeting power demands and can be regarded as a long-term energy storage device, and a battery or a capacitive energy storage device serves as a short-term energy source for buffering power demand fluctuation and can be regarded as a short-term energy storage device.

The load energy demands of an electric bus include a drive force energy demand needed for vehicle advancing and an energy demand needed for normal safe operation of various vehicle-mounted equipment such as a vehicle-mounted air conditioner and vehicle-mounted wifi. And the drive force energy demand accounts for a great part of energy demands and changes constantly along with the states of starting, stopping, accelerating and decelerating, high-speed running, low-speed running and the like of the bus.

In the present specific implementation mode, when the capacity of the energy storage devices is calculated by using the present method, the following steps should be performed. Firstly, a specific bus line running route needs to be analyzed, the typical historical required power data P_{usage} of the hybrid bus for round trips for one time for more than two hours (8427 seconds) on the specific bus line is recorded or obtained, and as shown in FIG. 2, the power value per second is regarded as the historical data of the required power in FIG. 2, so there are 8427 pieces of historical required power data in FIG. 2. Meanwhile, the 8427 pieces of historical required power data are added up and averaged to obtain the average value P_{usage avg} of the required power in more than two hours.

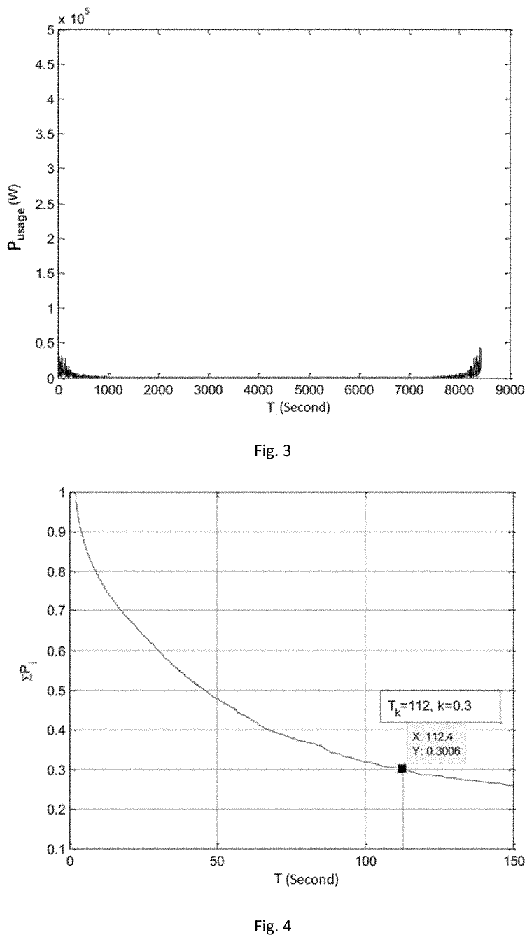

When the capacity of the short-term energy storage device is calculated, firstly, the abovementioned 8427 pieces of historical required power data needs to be subjected to rapid Fourier transformation, so that the relation between the required power and the frequency is obtained, that is, a power-frequency relation diagram similar to a spectrum diagram as shown in FIG. 3.

In FIG. 3, a vertical coordinate is the required power data P_{usage}, a horizontal coordinate is the frequency f, but in order to make display more obvious, the frequency value in FIG. 3 is transformed into the time period value T corresponding to the frequency value, and T is equal to 1/f.

Due to time duration limitation of rapid Fourier transformation, only data within half of time (namely 4214 seconds) of the whole calculation duration (8427 seconds here) needs to be analyzed subsequently after transformation. The required power corresponding to 4214 seconds are added up to obtain the required power total quantity, and then the required power of 4214 seconds is divided by the required power total quantity to obtain a series of specific values Pᵢ greater than 0 but smaller than 1, namely, per-unit value normalization is achieved.

Then, the specific values Pᵢ are accumulated period by period in the direction from a value with a large period (namely the frequency is low and the fluctuation is small, the period corresponding to 4214 seconds here) to a small period (here, the accumulation last period is from a period corresponding to 4214 seconds to a period corresponding to 1 second, and there are 4214 pieces of data), an accumulated value ΣPᵢ of a series of specific values Pᵢ is obtained, so that a relation curve of the accumulated value and the periods is obtained, as shown in FIG. 4. In the relation curve, the accumulated value ΣPᵢ corresponds to the percentage of the required power accumulated value with a period greater than or equal to the corresponding period Tᵢ of an abscissa axis to the whole required power total quantity. Then one long and short term critical percentage k is selected, the corresponding period Tₖ is found out, the period duration smaller than Tₖ can be regarded to need to be buffered by the short-term energy storage device, and therefore the capacity of the short-term energy storage device can be calculated out as P_{usage avg}*Tₖ. For example, the long and short term critical percentage k=0.3 is selected, and the corresponding period Tₖ=112 seconds is found, so that the capacity of the short-term energy storage device is calculated as the capacity obtained by multiplying 112 seconds by the average required power, namely the capacity of the short-term energy storage device.

When the capacity of the long-term energy storage device is calculated, firstly, a series of bus required power historical data P_{usage} is subtracted from the average required power P_{usage avg}, that is, P_{Δi}=P_{usage avg}−P_{usage}, a series of hypothetical supply and demand mismatch power data P_{Δi} is obtained (there are 8427 pieces of data here), then the 8427 pieces of data P_{Δi} are connected end to end, and then the maximum value of the sum of any q connected data is calculated out, wherein q is a natural number greater than or equal to 1 but smaller than or equal to 8427, and the capacity corresponding to the maximum value is the capacity of the long-term energy storage device.

After the capacity of the long-term energy storage device is calculated, the capacity also needs to be converted into a volume corresponding to the long-term energy storage device. As a long-term energy storage source provider here is fossil fuel of the hybrid bus, the calculated capacity of the long-term energy storage device needs to be converted into a volume of the fossil fuel. That is, the volume is obtained by dividing the calculated capacity of the long-term energy storage device by the energy density of the fossil fuel per unit volume and then dividing the result by the efficiency for burning the fossil fuel.

The obtained capacity of the short-term energy storage device and the capacity of the long-term energy storage device are added up to obtain the capacity of the energy storage devices in the hybrid bus.

Besides, factors such as efficiency of an electric power conversion device, safety margins and safety limits of the energy storage devices, load increase of an air conditioner in winter and summer and drive power demand increase at rush hours also need to be considered. The calculated capacity of the energy storage devices are multiplied by a capacity coefficient C₁ and a capacity coefficient C₂, and therefore the final capacity of the energy storage devices in the hybrid bus is obtained, wherein C₁ is the capacity coefficient of the long-term energy storage device, C₂ is the capacity coefficient of the short-term energy storage device, 1≤C1≤2, and 1≤C2≤2.

Compared with the prior art, the method for measuring the capacity of the energy storage devices in the hybrid bus provided by the present disclosure can rapidly and accurately determine the capacity of the short-term energy storage device and the long-term energy storage device by recording or obtaining the historical required power data of the hybrid bus, so as to greatly reduce the cost of the energy storage devices and the whole bus on the premise of ensuring continuous and reliable running of the hybrid bus.

1. A method for measuring capacity of energy storage devices in a hybrid bus, comprising the following steps:
obtaining an actual load energy demand value of the hybrid bus for round trips on a selected bus line for one or more times per unit time, namely, required power P_{usage}, and then adding up and averaging corresponding required power within a needed time range of the hybrid bus for round trips on the selected bus line for one or more times so as to obtain average required power P_{usage avg};
determining energy storage capacity of a short-term energy storage device of the hybrid bus, comprising steps of
carrying out Fourier transformation on the required power P_{usage} to obtain a relation model between the required power P_{usage} and time periods, wherein a vertical axis is data of the required power P_{usage}, an abscissa axis is values of the time periods T=1/f, and f is frequency;
carrying out per-unit value normalization on the corresponding required power corresponding to each time period within not more than half of the time in the time range required by the hybrid bus for round trips on the selected bus line for one or more times, so as to obtain a specific value Pᵢ after per-unit value normalization, and accumulating the required power obtained after per-unit value normalization period by period to obtain an accumulated value ΣPᵢ, of a series of required power values after per-unit value normalization, wherein 0<Pᵢ<1; and
establishing a relation curve of the accumulated value ΣPᵢ and the time periods, selecting one short and long term critical percentage k from the relation curve, determining a period Tₖ corresponding to k and judging that a period duration smaller than Tₖ needs to be buffered by the short-term energy storage device, so as to determine the energy storage capacity of the short-term energy storage device as P_{usage avg}*Tₖ, wherein ΣPᵢ corresponds to a percentage of the required power accumulated value with a period greater than or equal to a corresponding time period Tᵢ of the abscissa axis to a whole required power total quantity, and 0.2<k<0.4; and
determining energy storage capacity of a long-term energy storage device of the hybrid bus, comprising steps of calculating n supply and demand mismatch power P_{Δi}, wherein P_{Δi}=P_{usage avg}−P_{usage}, connecting the obtained n P_{Δi} end to end, and then calculating a maximum value of the sum of any q connected data, wherein the obtained maximum value is the energy storage capacity of the long-term energy storage device, n is a positive integer, and q is a natural number which is greater than or equal to 1 but smaller than or equal to n.

2. The method according to claim 1, wherein in the step of determining the energy storage capacity of the short-term energy storage device, per-unit value normalization is carried out on the corresponding required power corresponding to each time period within half of the time required by the hybrid bus for round trips on the selected bus line for one or more times.

3. The method according to claim 2, wherein in the step of determining the energy storage capacity of the short-term energy storage device, the required power corresponding to each time period within half of the time required by the hybrid bus for round trips on the selected bus line for one or more times is added up to obtain a required power total quantity, and then the required power of each period is divided by the required power total quantity to obtain a series of decimals Pᵢ, so that per-unit value normalization is achieved.

4. The method according to claim 1, wherein in the step of determining the energy storage capacity of the short-term energy storage device, the required power values after per-unit value normalization are accumulated period by period from a value with a large period, to obtain the accumulated value ΣPᵢ of a series of required power values after per-unit value normalization, wherein the value with the large period is a value with low frequency and small fluctuation.

5. The method according to claim 1, further comprising a step of calculating a volume of liquefied fuel required to be stored in the long-term energy storage device according to the energy storage capacity of the long-term energy storage device, wherein the volume of the liquefied fuel is obtained by dividing the energy storage capacity of the long-term energy storage device by energy density per unit volume of the liquefied fuel and then dividing by efficiency of burning the liquefied fuel.

6. The method according to claim 1, further comprising a step of multiplying the energy storage capacity of the long-term energy storage device and the energy storage capacity of the short-term energy storage device by a margin coefficient C₁ of the energy storage capacity of the long-term energy storage device and a margin coefficient C₂ of the energy storage capacity of the short-term energy storage device, respectively, wherein 1≤C₁≤2, and 1≤C₂≤2.

7. The method according to claim 6, wherein values of C₁ and C₂ are related to extra influence factors, and the extra influence factors comprise at least one selected from a group consisting of efficiency of an electric power conversion device, safety margins and safety limits of the energy storage devices, load increases of an air conditioner in winter and summer and drive power demand increases at rush hours.

8. The method according to claim 1, wherein load energy demands of the hybrid bus comprise a drive force energy demand needed for vehicle advancing and an energy demand needed for normal safe operation of vehicle-mounted equipment.

9. The method according to claim 1, wherein the long-term energy storage device is a fuel energy storage device.

10. The method according to claim 1, wherein the short-term energy storage device is a battery or a capacitive energy storage device.
